(19) United States
(12) Patent Application Publication
(10) Pub. No.: US 2005/0164748 A1
(43) Pub. Date: Jul. 28, 2005

(54) Mobile communication terminal and communication system

(75) Inventor: Mitsuhiro Kitaji, Yokohama-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/035,002

(22) Filed: Jan. 12, 2005

(30) Foreign Application Priority Data
Jan. 28, 2004 (JP) 2004-019975

(51) Int. Cl. G11C 8/00

(52) U.S. Cl. 455/572; 455/550.1

(57) ABSTRACT

Predetermined information from, for example, a phonebook or dialed and answered call record information is stored in a memory. A control unit compares the voltage of a battery, monitored by a battery monitoring unit, to a threshold value. When the battery voltage falls below the threshold value, the predetermined information is read from the memory unit and written into a RFID unit. The remaining voltage in the battery is used as the power necessary for this reading and writing. When a reader is operated, a radio wave is transmitted via an antenna from a wireless communication unit and received by an antenna of a mobile telephone. Thereby, power is generated in an RFID unit, which transmits the stored information to the antenna of the reader by using this power. A control unit displays this information in a display unit.

### PRIORITY CLAIM

Priority is claimed on Japanese Patent Application No. 2004-19975, filed Jan. 28, 2004, the content of which is incorporated herein by reference.

### BACKGROUND OF THE INVENTION

1. Field of the Invention

The present invention relates to a mobile communication terminal such as a mobile telephone that stores phonebook information and dialed and received call record information and the like, a communication apparatus that reads the stored phonebook information and the dialed and received call record information and the like from this mobile communication terminal externally; and a communication system formed by this mobile communication terminal and the communication apparatus.

2. Description of Related Art

In a mobile telephone, which typifies conventional mobile communication terminals, phonebook information and dialed and received call record information are stored in an internal memory. When a user wishes to make a telephone call or search for phone numbers or email addresses or the like, the user accesses the memory by operating the mobile telephone and searches the information in the phonebook and the dialed and received call record or the like. However, in the case that the battery of the mobile telephone is dead and cannot be charged, in a town, for example, it is not possible to search for telephone numbers, email addresses or the like.

As a countermeasure, a technology has been proposed wherein, for example, a phonebook mode is provided in the mobile telephone, it is determined whether or not the battery voltage has fallen below a predetermined voltage, and in the case that it is determined that the battery is low, the mobile telephone switches to an energy saving phonebook mode, and functions other than those necessary for displaying the phonebook by the display are suspended. Thereby, the content of the phonebook can be verified to a minimum extent by using the liquid crystal display.

In addition, conventionally technology relating to a dialed and received call record memory has been proposed (refer, for example, to Citation 1: Japanese Unexamined Patent Application, First Publication, No. 2001-268208).

However, in this conventional technology, although telephone numbers and the like can be checked as long as the phonebook can be displayed even when the battery voltage falls below a predetermined value, in the case that the battery voltage falls further and display in the liquid crystal display is no longer possible, there is the problem that telephone numbers and the like cannot be checked. In addition, if the liquid crystal display screen of the mobile telephone has been damaged and can no longer be used, or if the mobile telephone has been broken, there is the problem that searching the phonebook and the like from the memory becomes impossible.

In consideration of the problems described above, it is an object of the present invention to allow the reading of the phonebook and dialed and received call record information and the like in mobile communication terminal by an external apparatus, even in the cases that the power source of the mobile communication terminal cannot be turned on or the display cannot be used.

### SUMMARY OF THE INVENTION

A mobile communication terminal according to the present invention is characterized in comprising a first memory for storing predetermined information during normal operation; a non-volatile second memory that can be attached or detached; a detection unit for detecting a remaining battery level; and a control unit for storing predetermined information that has been stored in the first memory in the second memory when it is detected that the remaining battery level has fallen below a predetermined value.

In addition, a mobile communication terminal according to the present invention is characterized in comprising a first memory for storing predetermined information during normal operation; a second memory for storing information, the stored information being read by non-contact communication; a detection unit for detecting the remaining battery level; and a control unit for storing the predetermined information that has been stored in the first memory in the second memory when it has been detected that the remaining battery level has fallen below a predetermined value.

In addition, a communication system according to the present invention is formed by a mobile communication terminal having a first memory for storing predetermined information during normal operation; a second memory for storing information, the stored information being read by non-contact communication; a detection unit for detecting a remaining battery level; and a control unit for storing the predetermined information that has been stored in the first memory in the second memory when it has been detected that the remaining battery level has fallen below a predetermined value, and a communication apparatus having a receive unit for receiving the predetermined information that has been stored in the second memory by non-contact communication, and a transmit unit for carrying out transmitting processing based on the predetermined information that has been received by the receive unit.

In addition, a mobile communication terminal according to the present invention is characterized in comprising a first memory that stores predetermined information during normal operation; a non-volatile second memory that can be attached or detached; a detection unit that detects dialed and received calls; and a control unit that stores the predetermined information that has been stored in the first memory in the second memory when the detection unit has detected dialed or received calls.

In addition, a mobile communication terminal according to the present invention is characterized in comprising a first memory for storing predetermined information during normal operation; a second memory for storing information, the stored information being read by non-contact communication; a detection unit for detecting dialed and received calls; and a control unit for storing the predetermined information that has been stored in the first memory in the second memory when the detection unit has detected dialed and received calls.

In addition, a communication system according to the present invention is characterized in comprising a mobile communication terminal that provides a first memory for storing predetermined information during normal operation; a second memory for storing information, the stored information being read by non-contact communication; a detection unit for detecting dialed and received calls; and a control unit for storing predetermined information that has been stored in the first memory in the second memory when the detection unit has detected dialed and received calls; and a communication apparatus having a receive unit for receiving predetermined information that has been stored in the second memory by non-contact communication, and a transmit unit for carrying out transmitting processing based on the predetermined information received by the receive unit.

In addition, a mobile communication terminal according to the present invention is characterized in comprising a first memory for storing predetermined information during normal operation; a non-volatile second memory that can be attached or detached; a clock unit for clocking time; and a control unit for storing predetermined information that has been stored in the first memory in the second memory each time the clock unit clocks a predetermined time starting when the predetermined information that has been stored in the first memory is stored in the second memory.

In addition, a mobile communication terminal according to the present invention is characterized in comprising a first memory for storing predetermined information during normal operation; a second memory for storing information, the stored information being read by non-contact communication; a clock unit for clocking time; and a control unit for storing predetermined information that has been stored in the first memory in the second memory each time the clock unit clocks a predetermined time starting when the predetermined information that has been stored in the first memory is stored in the second memory.

In addition, a communication system according to the present invention is characterized in comprising a mobile communication terminal having a first memory for storing predetermined information during normal operation; a second memory for storing information, the stored information being read by non-contact communication; a clock unit for clocking time; and a control unit for storing predetermined information that has been stored in the first memory in the second memory each time the clock unit clocks a predetermined time starting when the predetermined information that has been stored in the first memory is stored in the second memory; and a communication apparatus having a receive unit for receiving predetermined information stored in the second memory by using non-contact communication; and a transmit unit for carrying out transmitting processing based on the predetermined information obtained by the receive unit.

According to the present invention, even in the case that the mobile communication terminal cannot be used, data that is either identical to or substantially identical to the data stored by the mobile communication terminal can be read by another apparatus.

### BRIEF DESCRIPTION OF THE DRAWINGS

FIG. 1 is a block diagram showing the communication system according to a first embodiment and second embodiment of the present invention.

FIG. 2 is a flowchart showing the operation when the battery voltage has become low according to the first embodiment of the present invention.

FIG. 3 is a flowchart showing the operation when there has been dialed and received calls according to the second embodiment of the present invention.

FIG. 4 is a block diagram showing a communication system according to a third embodiment of the present invention.

FIG. 5 is a block diagram showing a communication system according to a fourth embodiment of the present invention.

### DETAILED DESCRIPTION OF THE INVENTION

Below, the embodiments of the present invention are explained with reference to the figures.

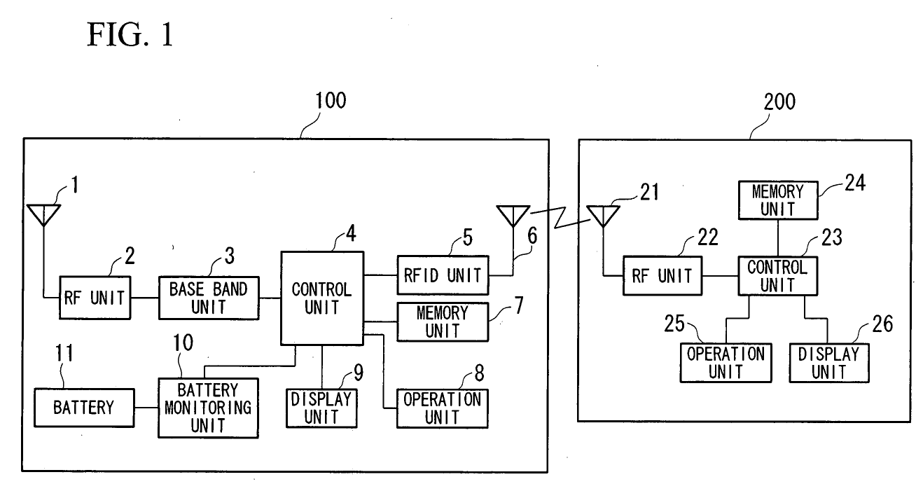

FIG. 1 is a block diagram showing the communication system according to the first and second embodiments of the present invention.

The present system is formed by a mobile telephone 100 that serves as the mobile communication terminal and a reader 200 that serves as the external apparatus. In the present embodiment, an example is explained in which a RFID (Radio Frequency Identification Device) is used as a rewritable device whose information stored therein can be read by non-contact communication externally without a power source.

The mobile telephone 100 is formed by an antenna 1, a wireless communication unit (RF unit) 2 that can communicate with a wireless public network, a base band unit 3, a control unit 4, a RFID unit 5 that allows rewriting of the stored information, an antenna 6 on the RFID unit 5, a memory unit 7, an operating unit 8, a display unit 9, a battery monitoring unit 10, and a battery 11.

Predetermined information that includes phonebook information that represents the names and telephone numbers, record information for dialed or received telephone numbers and sent or received email and the like are stored in the memory unit 7. In addition, the RFID unit is attached to a suitable location on the inner wall of the shell of the mobile telephone 100.

The reader 200 consists of an antenna 21 that communicates with the antenna 6, a wireless communication unit (RF unit) 22 that communicates with the RFID unit 5, a control unit 23, a memory unit 24, an operating unit 25, and a display unit 26.

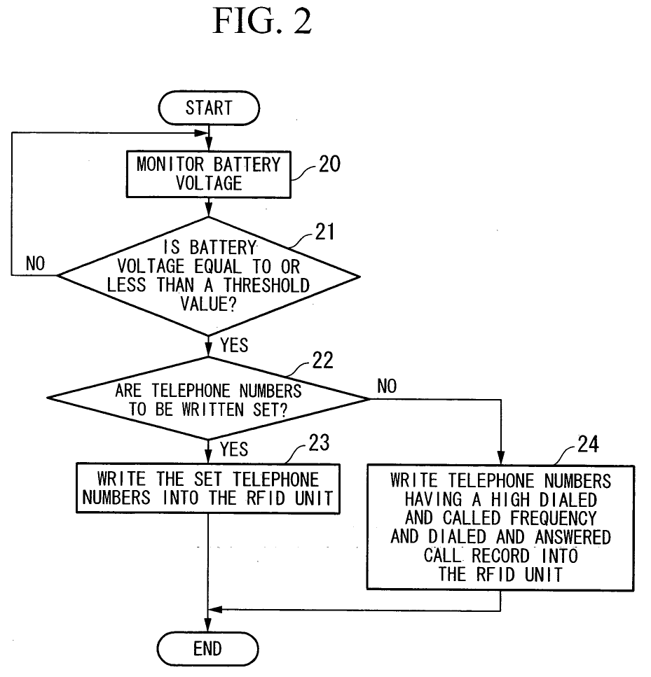

Next, the operation of the first embodiment having the structure described above will be explained with reference to the flowchart shown in FIG. 2.

In FIG. 1 and FIG. 2, the control unit 4 confirms the battery level, for example, a voltage, through the battery monitoring unit 10 (step 20) and compares this battery voltage with a predetermined threshold value (step 21). When the control unit 4 has determined that the battery voltage is higher than the threshold value, the processing returns to step 20, and the monitoring of the battery voltage continues.

When the control unit 4 has determined that the battery voltage is lower than the threshold value, it then determines whether or not among predetermined information in the memory unit 7, information such as telephone numbers that are to be written into the RFID unit 5 has been set in advance by the user (step 22). When the control unit 4 has determined that information has been set, it reads out that information such as the telephone numbers to be written into the RFID unit 5 from the memory 7, and writes these into the memory area of the RFID unit 5 (step 23). When the control unit 4 determines in step 22 that no information has been set, it writes telephone numbers having a high dialed and received frequencies and the dialed and received call record from the memory unit 7 into the memory area of the RFID unit 5 (step 24). The remaining power of the battery 11 serves as the power necessary for this reading and writing.

Note that even when the user has not specified any settings, predetermined information (dialed and received call record, newly registered data and the like) is stored in the RFID unit 5 when the battery voltage becomes low.

The information written into the RFID unit 5 can be read by non-contact communication from the outside by using the reader 200, even if the mobile telephone 100 cannot read the information under its own power after the voltage of the battery 11 has become even lower. By the user operating the operation unit 25 of the reader 200, a radio wave having a predetermined frequency is transmitted via the antenna 21 by the wireless communication unit 22 and received by the antenna 6 of the mobile telephone 100. Thereby, power is generated in the RFID unit 5, and the information written into the RFID unit can be transmitted to the reader 200 by using this power. The control unit 23 displays the information received in this manner on the display unit 26. This information is stored in the memory unit 24 as necessary.

According to the above processing, even when the battery of the mobile telephone 100 has died or the mobile telephone 100 is damaged, telephone numbers, email addresses, and information in the phonebook and dialed and received call record that has a high dialed and received call frequencies can be read from the outside by using the reader 200. Note that the value to the dialed and received call frequencies may depend, for example, on the number of times dialed and received or the number of times dialed and received during a predetermined time interval. The dialed and received frequencies can also denote the dialed frequencies, the received frequencies, or a combination of both.

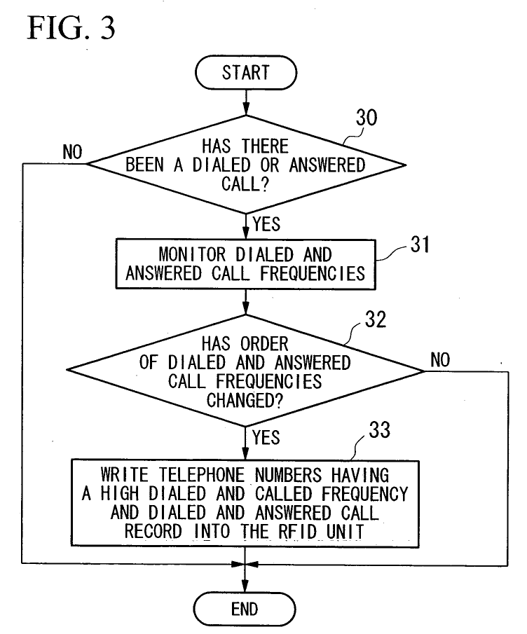

Next, the operation of the second embodiment will be explained with reference to the flowchart shown in FIG. 3.

When the mobile telephone 100 is dialed or the mobile telephone 100 is received (step 30), the control unit 4 searches the memory unit 7, and updates each of the dialed and received call frequencies based on the dialed or received telephone number, sent or received email address and the like (step 31). Here, the dialed and received call frequencies denotes the dialed frequencies and the received frequencies as described above, and, for example, the number of times dialed and the number of times received can be represented by counting.

Note that in the present embodiment, the several items having the higher number of times dialed or number of times received are written into the RFID unit 5.

Next, following step 31, the items written into the RFID unit 5 and the items having the highest dialed and received frequencies after being updated as described above are compared (step 32). As a result of this comparison, in the case that the items written into the RFID unit 5 and the items having the highest dialed and received call frequencies after being updated do not match, the control unit 4 writes the items having the highest dialed and received call frequencies after being updated into the RFID unit 5 (step 33).

According to the above processing, the new items having a high dialed and received call frequencies can always be written into the RFID unit 5, and in the case that the battery has died or in the case that searches of telephone numbers or the like cannot be carried out by user operation due to damage to the mobile telephone 100, it is possible to read the minimum information for telephone numbers, email addresses and the like from the outside by using the reader 200. Note that step 32 and step 33 of the second embodiment can be applied to step 24 in FIG. 2 of the first embodiment.

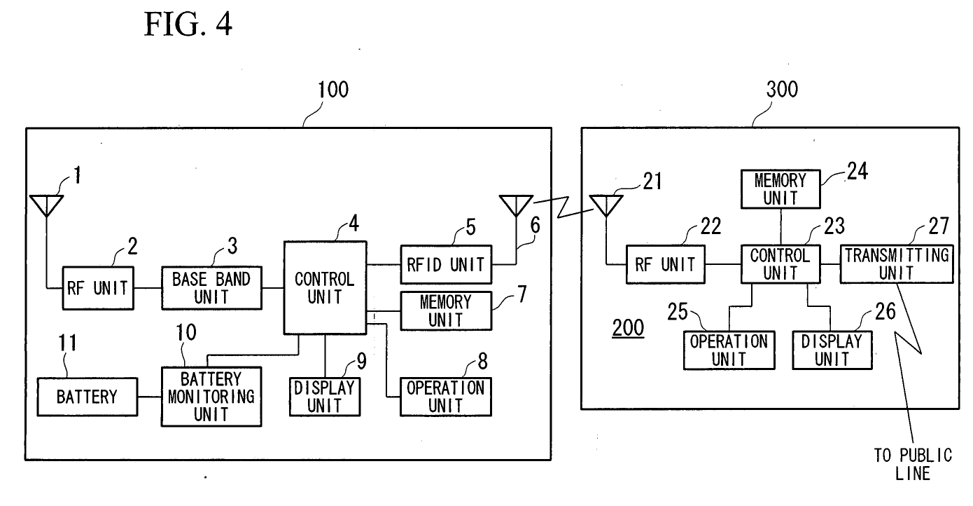

Next, a third embodiment that uses a communication apparatus having the reader 200 will be explained with reference to FIG. 4.

FIG. 4 is a block diagram showing the communication system according to the third embodiment of the present invention, and parts corresponding to those in FIG. 1 are denoted by identical reference numerals and redundant explanations have been omitted.

The communication system shown in FIG. 4 consists of a mobile telephone 100 that serves as a mobile communication terminal and a communication apparatus 300 that can be connected to a public line and is equipped with a reader 200.

The communication apparatus 300 provides a communication unit 27 that allows the connection of the reader 200 in FIG. 1 to a public line. The communication unit 27 that connects to a public line can provide either a wired line or a wireless line. Therefore, the communication apparatus 300 according to the present embodiment, for example, is an apparatus such as a home phone, a public telephone, a mobile telephone, a personal computer or the like that is equipped with the reader 200. However, this is not limiting, and an apparatus having an equivalent function can be used.

Next, the operation of this communication system will be explained.

When the information in the memory unit 7 cannot be accessed due to damage to the mobile telephone 100 or due to the battery of the mobile telephone 100 dying, the communication apparatus 300 is set to the data acquisition mode (the mode of operation in which the information in the RFID unit 5 of the mobile telephone 100 is acquisition), and the mobile telephone 100 is brought in proximity to the communication apparatus 300.

The communication apparatus 300 transmits a radio wave having a predetermined frequency using the wireless communication unit 22 via the antenna 21, and the mobile telephone 100, which has been brought in proximity to the communication apparatus 300, receives this radio wave at the antenna 6. Thereby, power is generated in the RFID unit 5 in the mobile telephone 100, and the data written in the RFID unit 5 is transmitted to the communication apparatus 300 by using this power. The control unit 32 of the communication apparatus 300 stores the information received from the mobile telephone 100 in the memory unit 24, and displays this information on the display unit 26. Then, based on the operation of the user, line connections are established via the communication unit 27 according to the information displayed in the display unit 26. For example, in the case that the received information consists of telephone numbers, a telephone number is called, or in the case that the received information consists of email addresses, an email address is set for the addressee, and an email is produced and transmitted.

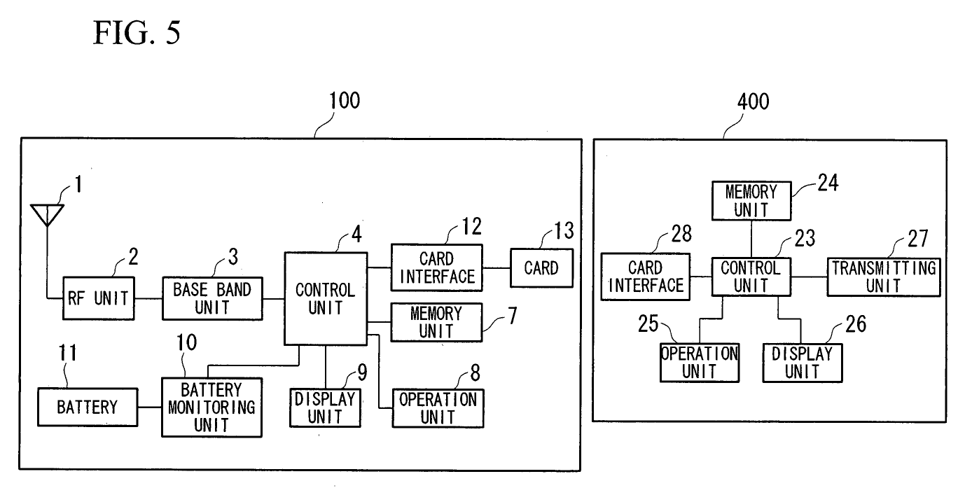

Next, a fourth embodiment, in which the mobile telephone 100 stores information on a non-volatile recording medium, will be explained with reference to FIG. 5.

FIG. 5 is a block diagram showing the communication system according to the fourth embodiment of the present invention. Parts corresponding to those in FIG. 1 are denoted by identical reference numbers and redundant explanations have been omitted.

The communication system in FIG. 5 is formed by a mobile telephone 100 that serves as a mobile communication terminal and a reader 400 that serves as an external apparatus.

Instead of the antenna 6 and the RFID unit 5 shown in FIG. 1, the mobile telephone 100 provides a card interface 12. The card interface 12 carries out reading and writing of data on the card 13, which consists of a non-volatile memory. In addition, instead of the antenna 21 and the wireless communication unit 22 shown in FIG. 1, the reader 400 provides a card interface 28 for carrying out reading and writing of data in the card 13. Note that the reader 400 provides a communication unit (either wired or wireless) that connects to a public line.

Similar to the case of writing data into the RFID unit 5 shown in FIG. 2 and FIG. 3, in the operation of the communication system according to the present embodiment, information is written into a card 13 via the card interface 12. In addition, in the cases that the information in the memory unit 7 cannot be accessed because the mobile telephone 100 has been damaged or the battery of the mobile telephone 100 has died, card 13, which can be attached to and detached from the mobile telephone 100, is detached from the mobile telephone 100 and attached in the reader 400. Thereby, it is possible to obtain the data in the card 13 by the reader 400 via the card interface 28. In addition, in the case that the reader 400 provides a communication unit 27 such as that shown in FIG. 4, it is possible to transmit to a public network via this communication unit 27.

Note that the information written into the RFID unit 5 and the card 13 is preferably administrative data for the dialed party represented by phonebook data and the like. However, considering the writing time and amount of data, more preferably the dialed call record data and the received call record data have a small amount of data and information for a destination party that is frequently contacted can be obtained. In addition, preferably a portion of the phonebook data (items having the highest usage frequencies) has a small amount of data and information about parties that are frequently contacted can be obtained. Note that the above is not limiting, and writing all necessary information does not depart from the spirit of the present invention. In addition, the dialed call record data and the received call record data are not limited to telephone numbers, but may also be information that identifies the destination party, such as email addresses.

In addition, in order to maintain security, methods such as the following are possible:
1. turning ON and OFF being read of the RFID by using a mechanical switch or an electrical or soft switch that uses the induction voltage generated during RFID operation; and
2. deleting the recorded content of the RIFD unit when the charging of the battery 11 of the mobile telephone 100 begins.

In the first embodiment explained above, explanations were provided for the case in which the source voltage of the battery falls below a threshold value and the case in which there is a dialing or receiving action. However, as a fifth embodiment, it is also possible to provide a timer (not illustrated) and carry out writing to the RFID unit or non-volatile memory information such as telephone numbers having a high dialed and received call frequencies and dialed and received call records each time a fixed time interval has passed by overwriting, or writing can be carried out by a user operation.

In addition, by limiting the information recorded in the second recording device of the RFID unit 5 to the “dialed and received call record information” when the battery voltage is low, the amount of information stored in the second memory device can be kept small, and it is possible to carry out storage reliably by effectively using the remaining voltage of the battery 11.

In addition, even when the battery voltage falls during a telephone call and the conversation is cut off, as long as the “dialed and received call record information” has been recorded, it is possible to redial immediately by using another telephone. In addition, even if only the “dialed and received call record information” is recorded, it is possible to verify information (telephone numbers, email addresses and the like) for the parties that are frequently contacted, and thus until the mobile communication terminal has been charged, this information is sufficient as necessary information.

Note that the mobile communication terminal in the present invention includes a mobile telephone, mobile information terminal and the like.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A mobile communication terminal comprises:
a first memory for storing predetermined information during normal operation;
a non-volatile second memory that can be attached or detached;
a detection unit for detecting a remaining battery level; and
a control unit for storing predetermined information that has been stored in the first memory in the second memory when it is detected that the remaining battery level has fallen below a predetermined value.

2. A mobile communication terminal comprises:
a first memory for storing predetermined information during normal operation;
a second memory for storing information, the stored information being read by non-contact communication;
a detection unit for detecting the remaining battery level; and
a control unit for storing the predetermined information that has been stored in the first memory in the second memory when it has been detected that the remaining battery level has fallen below a predetermined value.

3. A mobile communication terminal according to claim 1, wherein the predetermined information is phonebook information.

4. A mobile communication terminal according to claim 2, wherein the predetermined information is phonebook information.

5. A mobile communication terminal according to claim 1, wherein the predetermined information is dialed and received call record information.

6. A mobile communication terminal according to claim 2, wherein the predetermined information is dialed and received call record information.

7. A mobile communication terminal according to claim 1, wherein the second memory is a RFID device.

8. A mobile communication terminal according to claim 2, wherein the second memory is a RFID device.

9. A communication system comprises:
a mobile communication terminal having a first memory for storing predetermined information during normal operation; a second memory for storing information, the stored information being read by non-contact communication; a detection unit for detecting a remaining battery level; and a control unit for storing the predetermined information that has been stored in the first memory in the second memory when it has been detected that the remaining battery level has fallen below a predetermined value; and
a communication apparatus having a receive unit for receiving the predetermined information that has been stored in the second memory by non-contact communication, and a transmit unit for carrying out transmitting processing based on the predetermined information that has been received by the receive unit.

10. A mobile communication terminal comprises:
a first memory that stores predetermined information during normal operation;
a non-volatile second memory that can be attached or detached;
a detection unit that detects dialed and received calls; and
a control unit that stores the predetermined information that has been stored in the first memory in the second memory when the detection unit has detected dialed and received calls.

11. A mobile communication terminal comprises:
a first memory for storing predetermined information during normal operation;
a second memory for storing information, the stored information being read by non-contact communication;
a detection unit for detecting dialed and received calls; and
a control unit for storing the predetermined information that has been stored in the first memory in the second memory when the detection unit has detected dialed and received calls.

12. A mobile communication terminal according to claim 10, wherein the predetermined information is dialed and received call record information.

13. A mobile communication terminal according to claim 11, wherein the predetermined information is dialed and received call record information.

14. A mobile communication terminal according to claim 10, wherein:
an updating unit for updating the dialed and received call frequencies stored in the first memory each time the detection unit detects dialed or received calls; and the control unit stores high frequency information for dialed and received calls in a second memory.

15. A mobile communication terminal according to claim 11, wherein:
an updating unit for updating the dialed and received call frequencies stored in the first memory each time the detection unit detects dialed or received calls; and the control unit stores high frequency information for dialed and received calls in a second memory.

16. A communication system comprises:
a mobile communication terminal having a first memory for storing predetermined information during normal operation; a second memory for storing information, the stored information being read by non-contact communication; a detection unit for detecting dialed and received calls; and a control unit for storing predetermined information that has been stored in the first memory in the second memory when the detection unit has detected dialed or received calls; and
a communication apparatus having a receive unit for receiving predetermined information that has been stored in the second memory by non-contact communication, and a transmit unit for carrying out transmitting processing based on the predetermined information received by the receive unit.

17. A mobile communication terminal comprises:
a first memory for storing predetermined information during normal operation;
a non-volatile second memory that can be attached or detached;
a clock unit for clocking time; and
a control unit for storing predetermined information that has been stored in the first memory in the second memory each time the clock unit clocks a predetermined time starting when the predetermined information that has been stored in the first memory is stored in the second memory.

18. A mobile communication terminal comprises:
a first memory for storing predetermined information during normal operation;
a second memory for storing information, the stored information being read by non-contact communication;
a clock unit for clocking time; and
a control unit for storing predetermined information that has been stored in the first memory in the second memory each time the clock unit clocks a predetermined time starting when the predetermined information that has been stored in the first memory is stored in the second memory.

19. A mobile communication terminal according to claim 17, wherein the predetermined information is phonebook information.

20. A mobile communication terminal according to claim 18, wherein the predetermined information is phonebook information.

21. A mobile communication terminal according to claim 17, wherein the predetermined information is dialed- and received call record information.

22. A mobile communication terminal according to claim 18, wherein the predetermined information is dialed and received call record information.

23. A mobile communication terminal according to claim 17, wherein the second memory device is a RFID device.

24. A mobile communication terminal according to claim 18, wherein the second memory device is a RFID device.

25. A communication system comprising:
a mobile communication terminal having a first memory for storing predetermined information during normal operation; a second memory for storing information, the stored information being read by non-contact communication; a clock unit for clocking time; and a control unit for storing predetermined information that has been stored in the first memory unit in the second memory each time the clock unit clocks a predetermined time starting when the predetermined information that has been stored in the first memory is stored in the second memory; and
a communication apparatus having a receive unit for receiving predetermined information stored in the second memory by using non-contact communication; and a transmit unit for carrying out transmitting processing based on the predetermined information obtained by the receive unit.
